(19) United States
(12) Patent Application Publication
(10) Pub. No.: US 2025/0357107 A1
(43) Pub. Date: Nov. 20, 2025

(54) RF PULSING ASSISTED LOW-K MATERIAL DEPOSITION WITH HIGH DENSITY

(71) Applicant: Applied Materials, Inc., Santa Clara, CA (US)

(72) Inventors: Kent Zhao, San Francisco, CA (US); Rui Lu, Santa Clara, CA (US); Xinyi Lu, Santa Clara, CA (US); Bo Xie, San Jose, CA (US); Chi-I Lang, Cupertino, CA (US); Li-Qun Xia, Cupertino, CA (US); Chidambara A. Ramalingam, Fremont, CA (US); Shankar Venkataraman, San Jose, CA (US)

(73) Assignee: Applied Materials, Inc., Santa Clara, CA (US)

(21) Appl. No.: 18/666,435

(22) Filed: May 16, 2024

(51) Int. Cl. H01L 21/02

(52) U.S. Cl. CPC H01L 21/02274; H01L 21/02167; H01L 21/0217; H01L 21/02211; H01L 21/02216; H01L 21/02222

(57) ABSTRACT

Exemplary semiconductor processing methods may include providing a silicon-containing precursor and a nitrogen-containing precursor to a processing region of a semiconductor processing chamber. A substrate may be disposed within the processing region of the semiconductor processing chamber. The methods may include forming a plasma of the silicon-containing precursor and the nitrogen-containing precursor in the processing region. The plasma may be at least partially formed by an RF power operating at less than or about 1,000 W, at a pulsing frequency less than or about 1,000 Hz, and at a duty cycle between about 10% and 90%. The methods may include forming a layer of material on the substrate. The layer of material may be or include a silicon-and-nitrogen-containing material.

### TECHNICAL FIELD

The present technology relates to deposition processes and chambers. More specifically, the present technology relates to methods of producing low-k materials utilizing RF pulsing during deposition.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the materials are removed relative to one another. Plasma-enhanced deposition may produce materials having certain characteristics. Many materials that are formed require additional processing to adjust or enhance the material characteristics of the material in order to provide suitable properties.

Thus, there is a need for improved systems and methods that can be used to produce high quality devices and structures. These and other needs are addressed by the present technology.

### SUMMARY

Exemplary semiconductor processing methods may include providing a silicon-containing precursor and a nitrogen-containing precursor to a processing region of a semiconductor processing chamber. A substrate may be disposed within the processing region of the semiconductor processing chamber. The methods may include forming a plasma of the silicon-containing precursor and the nitrogen-containing precursor in the processing region. The plasma may be at least partially formed by an RF power operating at less than or about 1,000 W, at a pulsing frequency less than or about 1,000 Hz, and at a duty cycle between about 10% and 90%. The methods may include forming a layer of material on the substrate. The layer of material may be or include a silicon-and-nitrogen-containing material.

In embodiments, the silicon-containing precursor may be or include octamethylcyclotetrasiloxane, 2,4,6,8-tetramethyl-2,4,6,8-tetravinylcyclotetrasiloxane, 2,4,6,8-tetramethylcyclotetrasiloxane, dimethyldimethoxysilane (DMDMOS), ethoxydimethylsilane, isobutylmethyldimethoxysilane, vinylmethyldimethoxysilane, trimethylsilane, 1,1,3,3-tetramethyl-1,3-dimethoxydisiloxane, 1,3-dimethyl-1,1,3,3-tetramethoxydisiloxane, methoxy(dimethyl)silylmethane, methyl(dimethoxy)silylmethane, bis(trimethylsilyl)methane, 1,3-diethoxy-1,3-dimethyl-1,3-disilacyclobutane (EMSCB), 1,1,3,3-tetramethyl-1,3-disilacyclobutane, 1,3-dimethyl-1,3-diphenyl-1,3-disilacyclobutane, hexamethyl cyclotrisilazane (HMCTZ), hexamethyldisilazane (HMDS), bis(dimethylamino)-dimethylsilane (BDMADMS), bis(vinyldimethylsilyl) amine (BVDMSA), 1,3,5-trivinyl-1,3,5-trimethyl cyclotrisilazane (3V3MCTZ), tris(dimethylamino) silane (TDMAS), or a combination thereof. The nitrogen-containing precursor may be or include diatomic nitrogen (N₂) or ammonia (NH₃). A temperature within the semiconductor processing chamber may be maintained at less than or about 450° C. while forming the layer of material on the substrate. A pressure within the semiconductor processing chamber may be maintained at less than or about 50 Torr while forming the layer of material on the substrate. The plasma may be at least partially formed by an RF power operating at a pulsing frequency less than or about 500 Hz. The plasma may be at least partially formed by an RF power operating at a duty cycle less than or about 50%. The layer of material may be characterized by a dielectric constant less than or about 4.50. The layer of material may be characterized by a density of greater than or about 1.95 g/cm³. The layer of material may be a silicon-carbon-and-nitrogen-containing material. The layer of material may be characterized by a breakdown voltage at 1×10⁻⁶ A/cm² of greater than or about 3.0 MV/cm.

The present technology may encompass semiconductor processing methods. The methods may include providing a silicon-and-carbon-containing precursor and a nitrogen-containing precursor to a processing region of a semiconductor processing chamber. A substrate may be disposed within the processing region of the semiconductor processing chamber. The methods may include forming a plasma of the silicon-and-carbon-containing precursor and the nitrogen-containing precursor in the processing region. The plasma may be at least partially formed by an RF power operating at between about 50 W and about 750 W, at a pulsing frequency less than or about 10,000 Hz, and at a duty cycle less than or about 90%. The methods may include forming a layer of material on the substrate. The layer of material may be or include a silicon-containing material. The layer of material may be characterized by a dielectric constant less than or about 4.50.

In embodiments, the silicon-and-carbon-containing precursor may further include oxygen. A temperature within the semiconductor processing chamber may be maintained at less than or about 500° C. while forming the layer of material on the substrate. The plasma may be at least partially formed by an RF power operating at a pulsing frequency less than or about 750 Hz. The plasma may be at least partially formed by an RF power operating at a duty cycle less than or about 70%. The layer of material may be characterized by a density of greater than or about 1.97 g/cm³.

The present technology may encompass semiconductor processing methods. The methods may include providing a silicon-and-carbon-containing precursor and a nitrogen-containing precursor to a processing region of a semiconductor processing chamber. A substrate may be disposed within the processing region of the semiconductor processing chamber. The methods may include forming a plasma of the silicon-and-carbon-containing precursor and the nitrogen-containing precursor in the processing region. The plasma may be at least partially formed by an RF power operating at between about 50 W and about 750 W, at a pulsing frequency less than or about 10,000 Hz, and at a duty cycle less than or about 90%. The methods may include forming a layer of material on the substrate. The layer of material may be or include a silicon-containing material. The layer of material may be characterized by a dielectric constant less than or about 4.50 and a density greater than or about 1.9 g/cm³.

In embodiments, the plasma may be at least partially formed by an RF power operating at less than or about 1,000 W and at a pulsing frequency less than or about 1,000 Hz. The layer of material may be or include a silicon-carbon-and-nitrogen-containing material.

Such technology may provide numerous benefits over conventional systems and techniques. For example, pulsing RF power may improve deposition characteristics. For example, pulsing RF power during deposition operations may result in an increased ion density in the plasma, that may result in a denser material being deposited. Additionally, by pulsing the RF power during deposition operations, the denser material may maintain a low dielectric constant. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows operations of an exemplary method of semiconductor processing according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Plasma enhanced deposition processes may energize one or more constituent precursors to facilitate material formation on a substrate. Any number of material materials may be produced to develop semiconductor structures, including conductive and dielectric materials, as well as materials to facilitate transfer and removal of materials. Conventional low dielectric constant (low-k) materials may be deposited by continuously applying RF power. However, this process may result in a material with an undesirable density. In attempts to increase density, dielectric constant may undesirably increase.

The present technology may overcome these issues by performing a deposition process while pulsing the RF power during the deposition of the low-k material. Much plasma processing in which low-k material is being deposited is performed at continuous RF power, which produces an ion density that may affect material properties by not controlling an amount (or ratio) of ions and radicals in the resultant plasma. In the present embodiments, the RF power may be pulsed during deposition to increase the ion density of the plasma while substantially maintaining the ion energy of the plasma. Additionally, while the RF power is off, ions in the plasma may die off and leave the radicals. The radicals may selectively break, reorganize, and/or form bonds that advantageously increase the density of the as-deposited material while maintaining and/or further reducing the dielectric constant of the as-deposited material.

Although the remaining disclosure will routinely identify specific deposition processes utilizing the disclosed technology, it will be readily understood that the systems and methods are equally applicable to other deposition chambers, as well as processes as may occur in the described chambers. Accordingly, the technology should not be considered to be so limited as for use with these specific deposition processes or chambers alone. The disclosure will discuss one possible system and chamber that may be used to perform deposition processes according to embodiments of the present technology before additional details according to embodiments of the present technology are described.

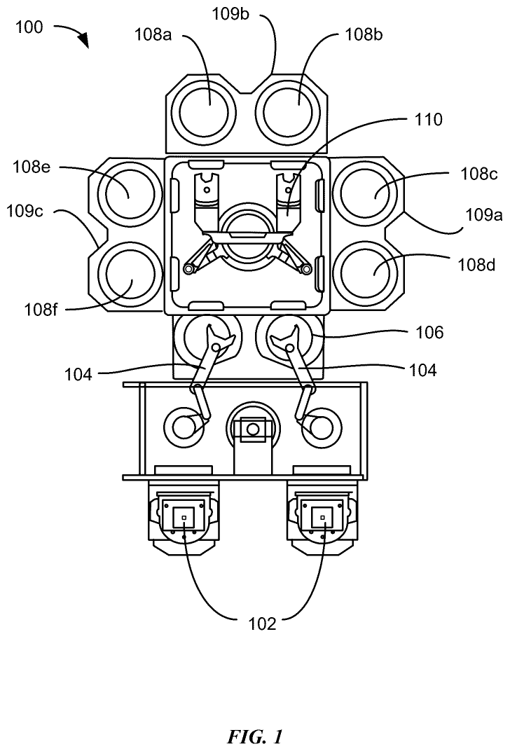

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other material on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric materials on the substrate. Any one or more of the processes described may be carried out in chambers separated from the fabrication system shown in different embodiments. It will be appreciated that additional configurations of deposition, etching, annealing, and curing chambers for dielectric materials are contemplated by system 100.

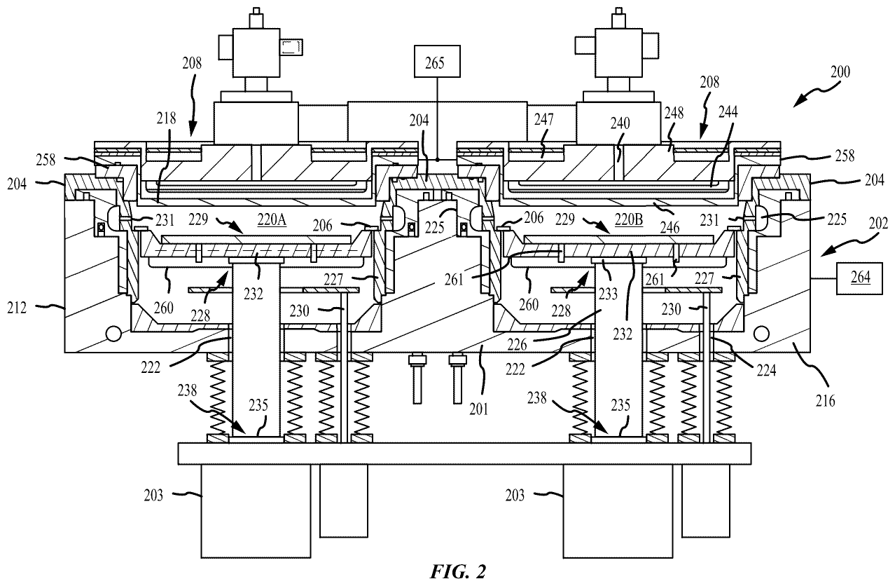

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include lid stack components according to embodiments of the present technology, and as may be explained further below. The plasma system 200 generally may include a chamber body 202 having sidewalls 212, a bottom wall 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the bottom wall 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a dual-channel showerhead 218 into the processing region 220B. The dual-channel showerhead 218 may include an annular base plate 248 having a blocker plate 244 disposed intermediate to a faceplate 246. A radio frequency (“RF”) source 265 may be coupled with the dual-channel showerhead 218, which may power the dual-channel showerhead 218 to facilitate generating a plasma region between the faceplate 246 of the dual-channel showerhead 218 and the pedestal 228. In some embodiments, the RF source may be coupled with other portions of the chamber body 202, such as the pedestal 228, to facilitate plasma generation. A dielectric isolator 258 may be disposed between the lid 204 and the dual-channel showerhead 218 to prevent conducting RF power to the lid 204. A shadow ring 206 may be disposed on the periphery of the pedestal 228 that engages the pedestal 228.

An optional cooling channel 247 may be formed in the annular base plate 248 of the precursor distribution system 208 to cool the annular base plate 248 during operation. A heat transfer fluid, such as water, ethylene glycol, a gas, or the like, may be circulated through the cooling channel 247 such that the base plate 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

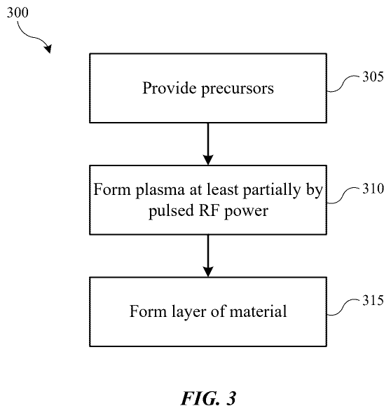

FIG. 3 shows operations of an exemplary method 300 of semiconductor processing according to some embodiments of the present technology. The method may be performed in a variety of processing chambers, including processing system 200 described above, as well as any other chamber in which plasma deposition may be performed. Method 300 may include a number of optional operations, which may or may not be specifically associated with some embodiments of methods according to the present technology.

Method 300 may include a processing method that may include operations for forming a layer of material, such as a film, or other deposition operations while pulsing RF power, which may result in low dielectric constant material with increased density. The method may include optional operations prior to initiation of method 300, or the method may include additional operations. For example, method 300 may include operations performed prior to the start of the method, including additional deposition, removal, or treatment operations. In some embodiments, method 300 may include flowing one or more precursors into a processing chamber at operation 305, which may deliver the precursor or precursors into a processing region of the chamber where a substrate may be housed, such as region 220, for example. In embodiments, the precursors may include a silicon-containing precursor and/or a nitrogen-containing precursor. The silicon-containing precursor and/or the nitrogen-containing precursor may further include oxygen, nitrogen, and/or hydrogen.

In some embodiments, the precursors may be or include a silicon-containing precursor and a nitrogen-containing precursor for producing a low-k dielectric layer, such as a silicon-and-nitrogen-containing material that may further include oxygen and/or hydrogen. The precursors may or may not include delivery of additional precursors, such as carrier gases or one or more oxygen-containing precursors for depositing an oxide layer. In some embodiments, the deposition may utilize a single deposition precursor that includes silicon and nitrogen and/or oxygen and/or hydrogen. However, to avoid more complicated precursors with numerous constituents, multiple precursors may be used to introduce silicon, nitrogen, and/or oxygen and/or hydrogen. Although a carrier gas, such as an inert precursor, may be delivered with the deposition precursor, additional precursors intended to react with the deposition precursor and produce deposition products may not be used.

In embodiments, the precursors may include a silicon-containing precursor, such as a silicon-and-carbon-containing precursor, a silicon-and-oxygen-containing precursor, a silicon-oxygen-and-carbon-containing precursor, or any other silicon-containing precursor. Silicon-containing precursors that may be used may be or include, but are not limited to, octamethylcyclotetrasiloxane, 2,4,6,8-tetramethyl-2,4,6,8-tetravinylcyclotetrasiloxane, 2,4,6,8-tetramethylcyclotetrasiloxane, dimethyldimethoxysilane (DMDMOS), ethoxydimethylsilane, isobutylmethyldimethoxysilane, vinylmethyldimethoxysilane, trimethylsilane, 1,1,3,3-tetramethyl-1,3-dimethoxydisiloxane, 1,3-dimethyl-1,1,3,3-tetramethoxydisiloxane, methoxy(dimethyl)silylmethane, methyl(dimethoxy)silylmethane, bis(trimethylsilyl)methane, 1,3-diethoxy-1,3-dimethyl-1,3-disilacyclobutane (EMSCB), 1,1,3,3-tetramethyl-1,3-disilacyclobutane, 1,3-dimethyl-1,3-diphenyl-1,3-disilacyclobutane, hexamethyl cyclotrisilazane (HMCTZ), hexamethyldisilazane (HMDS), bis(dimethylamino)-dimethylsilane (BDMADMS), bis(vinyldimethylsilyl) amine (BVDMSA), 1,3,5-trivinyl-1,3,5-trimethyl cyclotrisilazane (3V3MCTZ), tris(dimethylamino) silane (TDMAS), or a combination thereof, as well as any other silicon-containing precursors that may be used in silicon-containing material formation.

The precursors may further include a nitrogen-containing precursor. Nitrogen-containing precursors that may be used may include, but are not limited to, diatomic nitrogen (N₂), ammonia (NH₃), hydrazine (N₂H₄), as well as any other nitrogen-containing precursors that may be used in silicon-containing material formation.

At operation 310, a plasma may be formed of the precursors within the processing region, such as by providing RF power to the faceplate to generate a plasma within processing region 220, although any other processing chamber capable of producing plasma may similarly be used. The plasma may be formed by pulsing RF power, instead of using continuous RF power. The RF power may cycle between cycles of being “on” and “off” repeatedly. During “on” cycles, the RF operating power may be greater than or about 50 W or less than or about 1,000 W. A pulsing frequency may be below about 100,000 Hz. A duty cycle may be between about 5% and 95%. Pulsing the RF power may increase the ion density while maintaining the average ion energy, as compared to continuous RF power. In conventional continuous processes, the ion density may be about 1×10¹⁶ ions per cubic meter, whereas embodiments of the present disclosure may feature an ion density greater than this amount, such as greater than or about 1×10¹⁸ or 1×10¹⁹ ions per cubic meter. The increased ion density may further reduce the dielectric constant of the deposited material while maintaining and/or increasing the density of the deposited material.

In embodiments of the present disclosure, the RF power may be at a higher level during “on” cycles than compared to conventional technologies. In conventional deposition processes of low-k materials, higher plasma RF power may adversely affect methyl incorporation and/or SiO/SiN bonding into the layer of material. However, the present disclosure has discovered that by cycling with increased plasma power, ion density may be increased compared to continuous RF power while maintaining a similar ion energy as continuous RF power. In embodiments, the RF power may be greater than or about 200 W, greater than or about 250 W, greater than or about 275 W, greater than or about 300 W, greater than or about 325 W, greater than or about 350 W, greater than or about 375 W, greater than or about 400 W, greater than or about 450 W, greater than or about 500 W, greater than or about 650 W, greater than or about 700 W, or higher. However, to maintain control of the deposition rate, which may increase with higher RF powers, the RF power may be less than or about 1,000 W, less than or about 950 W, less than or about 900 W, less than or about 850 W, less than or about 800 W, less than or about 750 W, less than or about 700 W, less than or about 650 W, less than or about 600 W, less than or about 550 W, less than or about 500 W, or less.

By reducing the duty cycle, ions in the plasma may die off due to their shorter lifespan while radicals remain present. The radicals may selectively break, reorganize, and/or form bonds that favorably impact density and/or dielectric constant while ions may erratically break, reorganize, and/or form bonds that do not impact density and/or dielectric constant in a controlled manner. As such, the duty cycle may be maintained at less than or about 90%, less than or about 85%, less than or about 80%, less than or about 75%, less than or about 70%, less than or about 65%, less than or about 60%, less than or about 55%, less than or about 50%, less than or about 45%, less than or about 40%, less than or about 35%, less than or about 30%, less than or about 25%, less than or about 20%, less than or about 15%, less than or about 10%, or less. While lowering duty cycle may have a somewhat limited effect on dielectric constant, lower duty cycles may more drastically increase density of the material.

By decreasing the pulsing frequency, the density of the material may be increased. Lower pulsing frequencies may also maintain and/or further reduce the dielectric constant while simultaneously increasing the density. In embodiments of the present disclosure, the pulsing frequency may be less than or about 5,000 Hz, less than or about 2,500 Hz, less than or about 1,500 Hz, less than or about 1,000 Hz, less than or about 750 Hz, less than or about 500 Hz, less than or about 400 Hz, less than or about 300 Hz, less than or about 250 Hz, less than or about 200 Hz, less than or about 150 Hz, less than or about 100 Hz, less than or about 75 Hz, less than or about 50 Hz, less than or about 25 Hz, less than or about 15 Hz, less than or about 10 Hz, less than or about 5 Hz, or lower. Reduced frequencies have been observed to increase the density and maintain and/or further reduce the dielectric constant of the material at the greatest rate, but frequencies greater than 5,000 Hz still provide increased properties compared to continuous RF power.

By pulsing the RF power, bonds in the forming layer of material may selectively be reorganized to increase density while maintaining and/or reducing dielectric constant. Without being bound by any particular theory, it is believed that the ions in the plasma may die off due to their shorter lifespan leaving radicals in the plasma. While the ions may break, reorganize, and/or form bonds, the remaining radicals may selectively break, reorganize, and/or form bonds that advantageously affect density and/or dielectric constant. As one non-limiting example, SiH and NH bonds in the forming layer of material may react with radicals, such as NH₂ radicals from NH₃ as a precursor, to form SiCH₃, SiCSi, and/or SiN. These replaced bonds may increase density while maintaining and/or reducing dielectric constant in the layer of material.

Pulsing the RF power may reduce the deposition rate of the layer of material compared to conventional continuous RF processes. Lower duty cycles may further reduce the deposition rate. However, the reduced deposition rate may advantageously increase control of the thickness of the layer of material which may be increasingly important especially in high aspect ratio layers. In embodiments, the deposition rate may be less than or about 500 A/min, and may be less than or about 400 A/min, less than or about 300 A/min, less than or about 200 A/min, less than or about 100 A/min, less than or about 80 A/min, less than or about 60 A/min, less than or about 50 A/min, less than or about 40 A/min, less than or about 30 A/min, or less.

The deposition may be performed at substrate or pedestal temperatures less than or about 550° C., which may be due to thermal budget issues at back end of line operations. Consequently, in some embodiments the deposition may occur at temperatures less than or about 525° C., less than or about 500° C., less than or about 475° C., less than or about 450° C., less than or about 425° C., less than or about 400° C., less than or about 375° C., less than or about 350° C., less than or about 325° C., less than or about 300° C., less than or about 275° C., less than or about 250° C., less than or about 225° C., less than or about 200° C., or lower. Additionally, the deposition may be performed at a pressure of less than or about 50 Torr, such as less than or about 40 Torr, less than or about 30 Torr, less than or about 20 Torr, less than or about 15 Torr, less than or about 10 Torr, less than or about 7 Torr, less than or about 5 Torr, less than or about 2 Torr, or lower.

Material formed in the plasma may be deposited on the substrate at operation 315, which may produce a layer of material on the substrate. The layer of material may include silicon-containing material. Depending on the precursors used, the layer of material may additionally include one or more of carbon, nitrogen, hydrogen, and/or oxygen. By pulsing the RF power, ion density in the plasma may be increased, which may densify the layer of material and, therefore, strengthen the layer of material, as compared to conventional methods using continuous RF power. Further, pulsing the RF power may maintain and even lower the dielectric constant of the layer of material being deposited.

As explained above, conventional technologies operating at continuous plasma power may cause the ion density to be lower than if the plasma power were pulsed, which may result in the mechanical strength of the material being lower than desired. By pulsing the RF power according to the present technology, low-k dielectric materials may be produced that may be characterized by a dielectric constant of less than or about 4.50, and may be less than or about 4.45, less than or about 4.40, less than or about 4.38, less than or about 4.36, less than or about 4.34, less than or about 4.32, less than or about 4.30, less than or about 4.28, less than or about 4.26, less than or about 4.24, less than or about 4.20, less than or about 4.18, less than or about 4.16, less than or about 4.14, less than or about 4.12, less than or about 4.10, less than or about 4.05, less than or about 4.00, less than or about 3.95, less than or about 3.90, less than or about 3.85, less than or about 3.80, less than or about 3.70, less than or about 3.60, less than or about 3.50, or less.

Unlike conventional continuous RF power technologies, which may be limited to lower densities, the present technology may deposit materials with a density of greater than or about 1.5 g/cm³. For example, the material may be characterized by a density or greater than or about 1.6 g/cm³, greater than or about 1.7 g/cm³, greater than or about 1.75 g/cm³, greater than or about 1.8 g/cm³, greater than or about 1.85 g/cm³, greater than or about 1.9 g/cm³, greater than or about 1.95 g/cm³, greater than or about 1.96 g/cm³, greater than or about 1.97 g/cm³, greater than or about 1.98 g/cm³, greater than or about 1.99 g/cm³, greater than or about 2.0 g/cm³, greater than or about 2.05 g/cm³, greater than or about 2.1 g/cm³, greater than or about 2.15 g/cm³, greater than or about 2.2 g/cm³, greater than or about 2.25 g/cm³, greater than or about 2.3 g/cm³, greater than or about 2.4 g/cm³, greater than or about 2.5 g/cm³, or more.

The deposited layer of material may be characterized by a breakdown voltage at 1×10⁻⁶ A/cm² of greater than or about 3.0 MV/cm, greater than or about 3.2 MV/cm, greater than or about 3.4 MV/cm, greater than or about 3.5 MV/cm, greater than or about 3.6 MV/cm, greater than or about 3.7 MV/cm, greater than or about 3.8 MV/cm, greater than or about 3.9 MV/cm, greater than or about 4.0 MV/cm, greater than or about 4.1 MV/cm, greater than or about 4.2 MV/cm, greater than or about 4.3 MV/cm, greater than or about 4.4 MV/cm, greater than or about 4.5 MV/cm, greater than or about 4.6 MV/cm, greater than or about 4.7 MV/cm, or higher. Consequently, the present technology may produce dielectric layers that may be characterized by high density and low dielectric constant, and that may substantially retain improved electrical performance.

The material characteristics produced by embodiments of the present technology may be related to an amount of methyl groups incorporated into the material, as well as an amount of non-methyl carbon incorporated within the material, such as CH₂ or CH, bonded within the material. The processing may release an amount of these materials, which may provide an amount of porosity to the material, while retaining an amount of methyl incorporation, which may facilitate lowering a dielectric constant of the material produced, whereas higher amounts of non-methyl carbon retained within the material may increase the dielectric constant above the values noted above. For example, in some embodiments, as-deposited materials produced according to the present technology may be characterized by a methyl or CH₃ percentage incorporated or retained within the material of greater than or about 0.01%, and may be characterized by a methyl incorporation within the material of greater than or about 0.02%, greater than or about 0.05%, greater than or about 0.1%, greater than or about 0.2%, greater than or about 0.3%, greater than or about 0.4%, greater than or about 0.5%, greater than or about 0.55%, greater than or about 0.6%, greater than or about 0.65%, greater than or about 0.7%, greater than or about 0.75%, greater than or about 0.8%, greater than or about 0.85%, greater than or about 0.9%, greater than or about 0.95%, greater than or about 1%, or higher. The methyl or CH₃ percentage incorporated or retained within the material may be characterized as an amount of the total bonding per unit thickness.

Additionally, a percentage of SiCSi may be greater than or about 0.01%, and may be characterized by a methyl incorporation within the material of greater than or about 0.02%, greater than or about 0.05%, greater than or about 0.1%, greater than or about 0.2%, greater than or about 0.3%, greater than or about 0.4%, greater than or about 0.5%, greater than or about 0.55%, greater than or about 0.6%, greater than or about 0.65%, greater than or about 0.7%, greater than or about 0.75%, greater than or about 0.8%, greater than or about 0.85%, greater than or about 0.9%, greater than or about 0.95%, greater than or about 1%, or higher. The percentage of SiCSi incorporated or retained within the material may be characterized as an amount of the total bonding per unit thickness. Further, a percentage of SiC and SiN, which may be related to density of the material, may be greater than or about 0.01%, and may be characterized by a methyl incorporation within the material of greater than or about 0.02%, greater than or about 0.05%, greater than or about 0.1%, greater than or about 0.2%, greater than or about 0.3%, greater than or about 0.4%, greater than or about 0.5%, greater than or about 0.55%, greater than or about 0.6%, greater than or about 0.65%, greater than or about 0.7%, greater than or about 0.75%, greater than or about 0.8%, greater than or about 0.85%, greater than or about 0.9%, greater than or about 0.95%, greater than or about 1%, or higher. The percentage of SiC and SiN incorporated or retained within the material may be characterized as an amount of the total bonding per unit thickness.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a silicon-containing precursor” includes a plurality of such silicon-containing precursors, and reference to “the layer of material” includes reference to one or more layers of material and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a silicon-containing precursor and a nitrogen-containing precursor to a processing region of a semiconductor processing chamber, wherein a substrate is disposed within the processing region of the semiconductor processing chamber;
forming a plasma of the silicon-containing precursor and the nitrogen-containing precursor in the processing region, wherein the plasma is at least partially formed by an RF power operating at less than or about 1,000 W, at a pulsing frequency less than or about 1,000 Hz, and at a duty cycle between about 10% and 90%; and
forming a layer of material on the substrate, wherein the layer of material comprises a silicon-and-nitrogen-containing material.

2. The semiconductor processing method of claim 1, wherein the silicon-containing precursor comprises octamethylcyclotetrasiloxane, 2,4,6,8-tetramethyl-2,4,6,8-tetravinylcyclotetrasiloxane, 2,4,6,8-tetramethylcyclotetrasiloxane, dimethyldimethoxysilane (DMDMOS), ethoxydimethylsilane, isobutylmethyldimethoxysilane, vinylmethyldimethoxysilane, trimethylsilane, 1,1,3,3-tetramethyl-1,3-dimethoxydisiloxane, 1,3-dimethyl-1,1,3,3-tetramethoxydisiloxane, methoxy(dimethyl)silylmethane, methyl(dimethoxy)silylmethane, bis(trimethylsilyl)methane, 1,3-diethoxy-1,3-dimethyl-1,3-disilacyclobutane (EMSCB), 1,1,3,3-tetramethyl-1,3-disilacyclobutane, 1,3-dimethyl-1,3-diphenyl-1,3-disilacyclobutane, hexamethyl cyclotrisilazane (HMCTZ), hexamethyldisilazane (HMDS), bis(dimethylamino)-dimethylsilane (BDMADMS), bis(vinyldimethylsilyl) amine (BVDMSA), 1,3,5-trivinyl-1,3,5-trimethyl cyclotrisilazane (3V3MCTZ), tris(dimethylamino) silane (TDMAS), or a combination thereof.

3. The semiconductor processing method of claim 1, wherein the nitrogen-containing precursor comprises diatomic nitrogen (N₂) or ammonia (NH₃).

4. The semiconductor processing method of claim 1, wherein a temperature within the semiconductor processing chamber is maintained at less than or about 450° C. while forming the layer of material on the substrate.

5. The semiconductor processing method of claim 1, wherein a pressure within the semiconductor processing chamber is maintained at less than or about 50 Torr while forming the layer of material on the substrate.

6. The semiconductor processing method of claim 1, wherein the plasma is at least partially formed by an RF power operating at a pulsing frequency less than or about 500 Hz.

7. The semiconductor processing method of claim 1, wherein the plasma is at least partially formed by an RF power operating at a duty cycle less than or about 50%.

8. The semiconductor processing method of claim 1, wherein the layer of material is characterized by a dielectric constant less than or about 4.50.

9. The semiconductor processing method of claim 1, wherein the layer of material is characterized by a density of greater than or about 1.95 g/cm³.

10. The semiconductor processing method of claim 1, wherein the layer of material comprises a silicon-carbon-and-nitrogen-containing material.

11. The semiconductor processing method of claim 1, wherein the layer of material is characterized by a breakdown voltage at 1×10⁻⁶ A/cm² of greater than or about 3.0 MV/cm.

12. A semiconductor processing method comprising:
providing a silicon-and-carbon-containing precursor and a nitrogen-containing precursor to a processing region of a semiconductor processing chamber, wherein a substrate is disposed within the processing region of the semiconductor processing chamber;
forming a plasma of the silicon-and-carbon-containing precursor and the nitrogen-containing precursor in the processing region, wherein the plasma is at least partially formed by an RF power operating at between about 50 W and about 750 W, at a pulsing frequency less than or about 10,000 Hz, and at a duty cycle less than or about 90%; and
forming a layer of material on the substrate, wherein the layer of material comprises a silicon-containing material, and wherein the layer of material is characterized by a dielectric constant less than or about 4.50.

13. The semiconductor processing method of claim 12, wherein the silicon-and-carbon-containing precursor further comprises oxygen.

14. The semiconductor processing method of claim 12, wherein a temperature within the semiconductor processing chamber is maintained at less than or about 500° C. while forming the layer of material on the substrate.

15. The semiconductor processing method of claim 12, wherein the plasma is at least partially formed by an RF power operating at a pulsing frequency less than or about 750 Hz.

16. The semiconductor processing method of claim 12, wherein the plasma is at least partially formed by an RF power operating at a duty cycle less than or about 70%.

17. The semiconductor processing method of claim 12, wherein the layer of material is characterized by a density of greater than or about 1.97 g/cm³.

18. A semiconductor processing method comprising:
providing a silicon-and-carbon-containing precursor and a nitrogen-containing precursor to a processing region of a semiconductor processing chamber, wherein a substrate is disposed within the processing region of the semiconductor processing chamber;
forming a plasma of the silicon-and-carbon-containing precursor and the nitrogen-containing precursor in the processing region, wherein the plasma is at least partially formed by an RF power operating at between about 50 W and about 750 W, at a pulsing frequency less than or about 10,000 Hz, and at a duty cycle less than or about 90%; and
forming a layer of material on the substrate, wherein the layer of material comprises a silicon-containing material, and wherein the layer of material is characterized by a dielectric constant less than or about 4.50 and a density greater than or about 1.9 g/cm³.

19. The semiconductor processing method of claim 18, wherein the plasma is at least partially formed by an RF power operating at less than or about 1,000 W and at a pulsing frequency less than or about 1,000 Hz.

20. The semiconductor processing method of claim 18, wherein the layer of material comprises a silicon-carbon-and-nitrogen-containing material.
